(19) United States
(12) Patent Application Publication
(10) Pub. No.: US 2020/0251622 A1
(43) Pub. Date: Aug. 6, 2020

(54) Conversion Element, Radiation-Emitting Semiconductor Device and Method for Producing a Conversion Element

(71) Applicant: OSRAM Opto Semiconductors GmbH, Regensburg (DE)

(72) Inventors: Dominik Eisert, Regensburg (DE); Yi Zheng, Lynnfield, MA (US); Victor Perez, Lawrence, MA (US); Juliane Kechele, Stadtbergen (DE); Johanna Strube-Knyrim, Weil (DE)

(21) Appl. No.: 16/269,458

(22) Filed: Feb. 6, 2019

(51) Int. Cl. H01L 33/50; H01L 33/00; C09K 11/55

(52) U.S. Cl. CPC H01L 33/502; C09K 11/55; H01L 33/0075; H01L 33/0083

(57) ABSTRACT

A conversion element, a radiation-emitting semiconductor device and a method for producing a conversion element are disclosed. In an embodiment a conversion element includes a ceramic luminescent material and a flux material, wherein the flux material has a boiling temperature above 1500° C. and/or a melting temperature below 1500° C., and wherein the flux material has a concentration in the conversion element between at least 0.01 wt % and at most 1 wt %.

### TECHNICAL FIELD

The invention relates to a conversion element, a radiation-emitting semiconductor device and a method for producing a conversion element.

### SUMMARY

Embodiments provide an improved conversion element for radiation-emitting semiconductor devices. Further embodiments provide a method by means of which a conversion element can be produced.

A conversion element is specified. The conversion element is intended to convert electromagnetic primary radiation of a first wavelength range into electromagnetic secondary radiation of a second wavelength range. The conversion element may in particular be formed as a conversion layer or a conversion platelet which can be applied onto a transparent carrier or a radiation-emitting semiconductor element with or without an adhesive.

According to one embodiment the conversion element comprises a ceramic luminescent material. The ceramic luminescent material is preferably permeable or transparent to electromagnetic radiation, in particular visible light. The ceramic luminescent material preferably converts electromagnetic primary radiation of a first wavelength range into electromagnetic secondary radiation of a second wavelength range, e.g., comprising greater wavelengths than the first wavelength range.

Further, in the conversion element can be one or more kinds of ceramic luminescent material. Different kinds of ceramic luminescent material lead to a conversion element which is configured to convert the electromagnetic primary radiation into electromagnetic secondary radiation of different wavelength ranges, e.g., different colors.

According to one embodiment the conversion element comprises a flux material. The flux material can be a chemical cleaning agent, flowing agent or purifying agent. The advantages of the flux material are that it allows for an enhanced wetting of the ceramic luminescent material and helps to remove the oxides on the surfaces of the ceramic luminescent material or materials by chemical reaction.

According to one embodiment the flux material has a boiling temperature above 1500° C. and/or a melting temperature below 1500° C. at sintering conditions. This means that the flux material is chosen accordingly.

According to one embodiment the flux material has a concentration in the conversion element between at least 0.01 wt % and at most 1 wt %. For example, the concentration is about 0.2 wt %. This concentration leads to a homogenous distribution of the flux material in the ceramic luminescent material. Furthermore, an out-coupling of the electromagnetic secondary radiation and thus an improved efficiency of the conversion element is obtained by adding the flux material. Further, it has surprisingly been found that if the concentration of the flux material exceeds 1 wt % the out-coupling of the electromagnetic secondary radiation decreases rapidly.

According to one embodiment a conversion element comprises a ceramic luminescent material and a flux material, wherein the flux material has a boiling temperature above 1500° C. and/or a melting temperature below 1500° C. and the flux material has a concentration in the conversion element between at least 0.01 wt % and at most 1 wt %.

According to one embodiment the flux material is selected from a group comprising metal halides or nitride compounds. Possible materials for the flux material are in particular, but not exclusively, metal chloride, metal fluoride or, for example, aluminum nitride. The metal can be, for example, alkaline or alkaline earth metals.

According to one embodiment the flux material is selected from a group comprising LiF, NaF, KF, SrF₂, CaF₂, BaF₂. In particular BaF₂ can be used as the flux material. These flux materials preferably have a boiling temperature above 1500° C. and/or a melting temperature below 1500° C. at sintering conditions.

According to one embodiment the ceramic luminescent material comprises at least one of the following elements or materials: alkaline metals, alkaline earth metals, rare earth metals, La, Y, Si, N, Al, O. For example, as an alkaline metal lithium can be part of the ceramic luminescent material. Preferably as alkaline earth metals strontium or/and calcium are used in the ceramic luminescent material. Rare earth metals used in the ceramic luminescent material can be, for example, europium or cerium. The concentration of the different elements can vary.

According to one embodiment the conversion element comprises grains and pores, wherein the grains are formed with the ceramic luminescent material and the pores are filled with a gas. The gas can preferably comprise more than 70% nitrogen and can be, for example, air or nitrogen. The grains have grain boundaries between other adjacent grains and adjacent pores. These grain boundaries can, among other things, comprise the flux material. A diameter of the grain, for example, the average diameter d50, can be preferably between at least 5 micrometers and at most 10 micrometers, and the diameter of the pore can be preferably between at least 0.1 micrometer and at most 1 micrometer.

This means that the grains have a greater diameter than the pores. The large diameter of the grains and the small diameter of the pores lead to a denser conversion element which has a higher efficiency due to less scattering of the electromagnetic radiation in the conversion element.

According to one embodiment, the conversion element has a relative density of between at least 93.0% and at most 96.0%. The relative density of the conversion element describes the ratio between the grains and the flux material on the one hand and the pores on the other hand. In this case, it means that 93.0% to 96.0% of the conversion element are grains and flux material. The residual value of at least 4.0% to at most 7.0% are pores. This relative density leads to an improved, denser conversion element, the efficiency of which can be improved by reducing scattering of the electromagnetic radiation. Furthermore, there is preferably no proportional relation between the relative density and the efficiency. The efficiency of the electromagnetic radiation depends not only on the relative density but also on the diameter of the grains.

Further, a radiation-emitting semiconductor device is specified. The radiation-emitting semiconductor device in particular comprises a herein described conversion element. Hence, all features disclosed for the conversion element are also disclosed for the radiation-emitting semiconductor device and vice versa.

According to one embodiment the radiation-emitting semiconductor device comprises a radiation-emitting semiconductor element. The radiation-emitting semiconductor element, such as a light-emitting diode chip or a laser diode chip, has an epitaxially grown semiconductor layer sequence with an active region which is suitable for generating electromagnetic radiation, in particular the electromagnetic primary radiation of a first wavelength range.

According to one embodiment the radiation-emitting semiconductor device comprises a conversion element. The conversion element is arranged to emit electromagnetic secondary radiation of a second wavelength range which is different from the first wavelength range. The conversion element is preferably arranged downstream of the radiation-emitting semiconductor element. The conversion element is set up to generate a partial conversion or a full conversion. This is particularly dependent on the ceramic luminescent material used and the thickness of the conversion element. “Downstream” means that at least 50%, and in particular at least 85%, of the radiation emitted by the radiation-emitting semiconductor element enters the conversion element.

The conversion element can be designed as a layer or platelet which, for example, is in direct contact with the radiation-emitting semiconductor element. In addition the conversion element may be in the form of a cladding in which the radiation-emitting semiconductor element is at least partially or completely embedded. It is also possible that the conversion element is arranged at a distance from a radiation-emitting semiconductor element, for example, fastened to the radiation-emitting semiconductor element using an adhesive or a potting material.

The conversion element is in particular a herein described conversion element.

For example, the thickness of the conversion element is between at least 100 micrometers and at most 150 micrometers. This leads to a lower scattering of the electromagnetic radiation of the conversion element in comparison to thicker conversion elements.

According to one embodiment the radiation-emitting semiconductor element emits an electromagnetic primary radiation of a first wavelength range in the spectral region of blue light. In particular, the conversion element is selected such that it efficiently absorbs the electromagnetic primary radiation of the first wavelength range in the spectral region of blue light.

According to one embodiment the conversion element converts electromagnetic primary radiation of the first wavelength range into electromagnetic secondary radiation of the second wavelength range in the spectral region of amber light.

For example, the color coordinate Cx of amber light is between at least 0.53 and at most 0.58 and the color coordinate Cy is between at least 0.39 and at most 0.42. The emission peak of amber light is in particular between at least 550 nanometers and at most 610 nanometers.

The herein described radiation-emitting semiconductor device is particularly suitable for being used in LED applications, in particular for automotive and industrial lighting applications.

Furthermore, a method for producing a conversion element is provided. Preferably by means of the method described herein the here described conversion element can be produced. This means that all features disclosed for the conversion element are also disclosed for the method for producing the conversion element and vice versa.

According to one embodiment of a method for producing a conversion element, a powder of a starting material is provided. The powder comprises a plurality of particles. The powder of the starting material has a diameter, for example, the average diameter d50, of the particles from between at least 0.1 micrometer and at most 1 micrometer.

The powder of the starting material can be, for example, CaAlSiN₃:Eu²⁺, (Sr,Ca)Al₂Si₂N₆:Eu²⁺ or SrLiAl₃N₄:Eu²⁺, which in particular can be used to generate electromagnetic secondary radiation of a second wavelength range in the spectral region of red light of the conversion element.

For a conversion element which emits electromagnetic secondary radiation of the second wavelength range in the spectral region of amber light the powder of the starting material is, for example, α-SiAlON:Eu²⁺.

For a second wavelength range in the spectral region of yellow light the powder is, for example, (La,Y)₃Si₆N₁₁:Ce³⁺.

According to one embodiment of the method a flux material is introduced into the powder of the starting material. The flux material can be added in different ways.

For example, the flux material can be added as a starting raw material when making the powder of the starting material. Further, it can be added into already made powders of the starting material. The addition of the flux material when making the powder of the starting material leads to an improved homogenization of the flux material and the starting material, since the particles of the powder of the starting material are coated with a flux material layer.

According to one embodiment of the method a mixture comprising the flux material and the powder of the starting material is obtained. Preferably the mixture consists of the flux material, and the powder of the starting material.

According to one embodiment of the method the mixture is sintered to obtain the conversion element. Sintering is a method used for producing ceramics under high pressure and at high temperatures. The shape of the ceramic is hereby retained.

According to one embodiment of the method the flux material has a lower melting temperature than the melting temperature of the powder of the starting material under sintering conditions. This advantageously leads to a liquid phase of the flux material at the powder particles' boundaries of the starting material. This can promote ion diffusion, grain growth and pore removing during sintering.

According to one embodiment the method for producing a conversion element comprises A) providing a powder of a starting material, B) introducing a flux material into the powder of the starting material, C) obtaining a mixture comprising the flux material and the powder of the starting material, and D) sintering the mixture to obtain the conversion element wherein the flux material has a lower melting temperature than the melting temperature of the starting material. For example, the method is performed in the specified order.

According to one embodiment of the method, the starting material is BaSrSiN:Eu. This starting material emits electromagnetic secondary radiation of a second wavelength range in the spectral region of amber light.

According to one embodiment of the method, in step C) the mixture is homogenized and mixed with a mortar and pestle. For instance, the mixture is mixed manually by an agate mortar.

According to one embodiment of method step C) the mixture is homogenized and mixed in a plastic jar which is mechanically stirred and further, the mixture is homogenized with a ball milling. The mixture is mixed in a plastic jar, for example, in a Thinky mixer ARE-500 at 1000 rpm for two minutes. Afterwards the mixture is finally mixed for at least five hours by ball milling. Thus, through mixing it is ensured that the flux material is distributed homogenously in the powder of the starting material.

According to one embodiment of the method the sintering occurs by a spark plasma sintering (SPS) machine. Here the mixture is put into a graphite die with, for example, a 20 millimeter inner diameter. The sintering occurs under a nitrogen atmosphere at a maximum current of 1500 A. The sintering takes about 1 minute to 1 hour. Here, the particles of the powder of the starting material grow to a network of the grains.

The advantage of using the SPS machine in comparison to other sintering machines is the fast heating rate and that a voltage is applied which leads to an improved sintering of the mixture.

According to one embodiment of the method the sintering temperature is between at least 1500° C. and at most 1600° C. For example, the sintering temperature is 1560° C.

According to one embodiment of the method, the sintering time is between at least 20 minutes and at most 50 minutes. It has surprisingly been found that if the sintering time is more than 50 minutes the efficiency of the out-coupling of the electromagnetic secondary radiation will be reduced. For example, the optimal sintering time is about 30 minutes.

According to one embodiment of the method, the sintering pressure is between at least 40 MPa and at most 60 MPa. For example, the sintering pressure is about 50 MPa.

According to one embodiment of the method the sintering temperature is between at least 1500° C. and at most 1600° C. and the sintering time is about 30 minutes and the sintering pressure is about 50 MPa.

An advantage of the thus produced and here described conversion element is a strong excitation intensity, a high application temperature, a high thermal conductivity and an excellent stability. This can be achieved by a ceramic luminescent material comprising a flux material which leads, after sintering, to larger grains and fewer as well as smaller pores. The larger grains and smaller pores lead to a denser conversion element which has a high efficiency due to less scattering of the electromagnetic radiation in the conversion element and an improved out-coupling of the electromagnetic secondary radiation.

Furthermore, the color coordinates and the scattering of the electromagnetic radiation are related. For example, if the scattering of the electromagnetic radiation is increased, the emitted electromagnetic secondary radiation of a second wavelength is shifted into the spectral region of red light. If the scattering of the electromagnetic radiation is reduced, the emitted electromagnetic secondary radiation of a second wavelength is shifted into the spectral region of amber light.

### BRIEF DESCRIPTION OF THE DRAWINGS

Further advantageous embodiments and developments of the conversion element, the radiation-emitting semiconductor device and the method for producing the conversion element will become apparent from the embodiments described below in connection with the figures.

In the figures:

FIGS. 1, 2, 3 and 4 show images of a scanning electron microscopy of a conversion element for explaining exemplary embodiments of here described conversion elements and methods;

FIG. 5 shows an image of a scanning electron microscopy of particles of a powder of a starting material according to an example;

FIG. 6 shows a schematic sectional view of a conversion element according to an example;

FIGS. 7 and 8 show schematic sectional views of a radiation-emitting semiconductor device according to an exemplary embodiment;

FIG. 9 shows a schematic sectional view of differently produced conversion elements according to an exemplary embodiment;

FIG. 10 shows a table of differently produced conversion elements and their different effects on the color coordinates, relative density and conversion efficiency.

FIGS. 11 and 12 show graphical views of color coordinates and luminous flux of different produced conversion elements;

FIG. 13 shows a schematic view of a method for producing a conversion element according to an exemplary embodiment; and

FIGS. 14 and 15 show schematic sectional views of a spark plasma sintering machine.

In the exemplary embodiments and figures identical or identically acting elements can each be provided with the same references. The illustrated elements and their proportions to each other are not to be regarded as true to scale but individual elements such as layers, components and areas may be oversized for better representability and/or better understanding.

### DETAILED DESCRIPTION OF ILLUSTRATIVE EMBODIMENTS

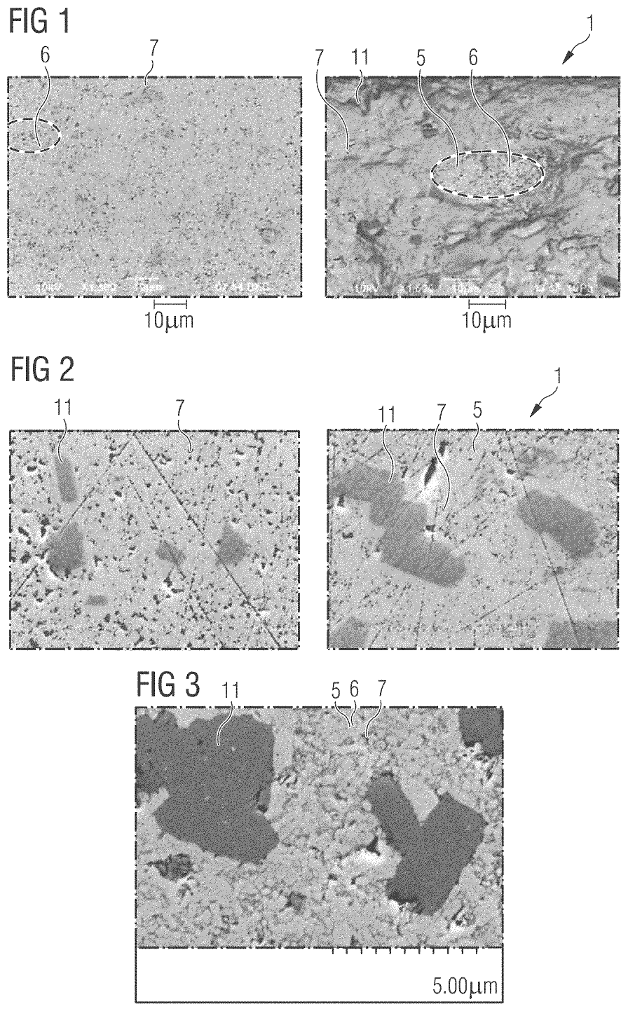

FIG. 1 shows images of a scanning electron microscopy of a conversion element 1 comprising pores 7 and grains 6.

The grains 6 are formed with the ceramic luminescent material and the pores 7 are filled with a gas. The gas can comprise more than 70% nitrogen and can be air or nitrogen. The ceramic luminescent material is intended to convert an electromagnetic primary radiation into electromagnetic secondary radiation of different wavelength ranges, e.g., colors. The ceramic luminescent material comprises at least one of the following elements or materials: alkaline metals, alkaline earth metals, rare earth metals, La, Y, Si, N, Al, O.

As an example, the SEM figure on the left shows a plurality of pores 7 and grains 6. Here, the conversion element 1 is synthesized without a flux material 5. The right-hand figure of FIG. 1 according to an exemplary embodiment shows a conversion element 1 with the flux material 5. In this case the flux material 5 is barium fluoride and its concentration within the conversion element is 0.5 wt %. Here we can see that fewer pores 7 are formed. Furthermore, the diameter of the grains 6 is larger and thus fewer grain boundaries 12 are obtained, which leads to less scattering on these grain boundaries 12. In addition, a secondary phase 11 is formed. The material of the secondary phase 11 depends on the ceramic luminescent material. The secondary phase 11 could be BaSi₇N₁₀.

In FIG. 2 a cross-section of a polished conversion element 1 obtained by an SEM is shown. In both figures a conversion element 1 comprising a plurality of pores 7 is shown. As an example, in the figure on the left-hand side no flux material 5 was used to obtain the conversion element 1. Here a plurality of pores 7 with a diameter of 0.5 to 5 micrometers is obtained.

A plurality of the pores 7 shows a diameter which is close to the wavelength of the electromagnetic radiation of a first wavelength in the spectral region of visible light, in particular blue light, and therefore leads to strong scattering of this electromagnetic radiation.

In comparison to the left-hand figure, the right-hand figure according to an exemplary embodiment shows fewer pores 7 and pores 7 with a diameter between at least 0.1 micrometer and at most 1 micrometer. This can be obtained by the addition of the flux material 5, e.g., barium fluoride. The plurality of the pores 7 shows a small diameter, which improves the efficiency by less scattering of the electromagnetic radiation of the primary and secondary radiation.

According to an exemplary embodiment in FIG. 3 a conversion element 1 which was poorly sintered is shown. Therefore the grains 6 show a smaller diameter than the grains 6 which are obtained under good sintering conditions, compare the right-hand figures in FIGS. 1 and 2. The diameter of the grains 6 is here between at least 0.5 μm and at most 2 μm. Furthermore, small pores 7 with a diameter of 0.1 μm and larger pores 7 with a diameter between at least 0.5 μm and at most 2 μm are shown. In addition a large secondary phase 11 could be obtained.

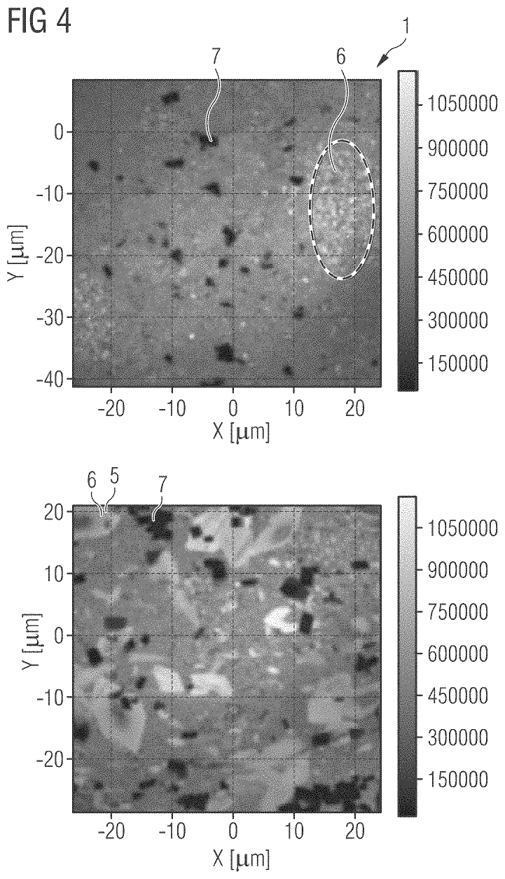

FIG. 4 shows two SEM figures of a conversion element 1. As an example for comparison, the conversion element 1 of the figure above is produced without a flux material 5 and the conversion element 1 of the figure below, according to an exemplary embodiment, is produced with a flux material 5. In the figure above no large areas are visible. Only some pores 7 and some small grains 6 are visible. In the figure below large grains 6 are visible. The grains 6 have a diameter of between at least 5 micrometers and at most 10 micrometers. The pores 7 are similar to those of the figure above. This shows that the flux material 5 in the conversion element 1 can lead to larger grains 6 without reducing the diameter of the pores 7.

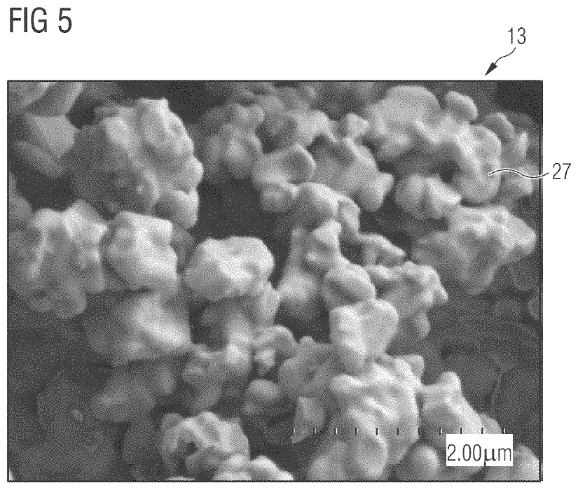

The example illustrated in FIG. 5 shows a powder of a starting material 13 in an SEM figure. The powder of the starting material 13 comprises a plurality of particles 27. The diameters of the particles 27 of the starting material 13 are between at least 0.1 μm and at most 1 μm. The powder of the starting material 13 can be, for example, CaAlSiN₃:Eu²⁺, (Sr,Ca)Al₂Si₂N₆:Eu²⁺ or SrLiAl₃N₄:Eu²⁺, which can be used to generate electromagnetic secondary radiation of a second wavelength range in the spectral region of red light of the conversion element 1. For a conversion element 1 which emits electromagnetic secondary radiation of the second wavelength range in the spectral region of amber light the powder of the starting material 13 is, for example, BaSrSiN:Eu, α-SiAlON:Eu²⁺ and for a second wavelength range in the spectral region of yellow light the powder is, for example, (La,Y)₃Si₆N₁₁:Ce³⁺.

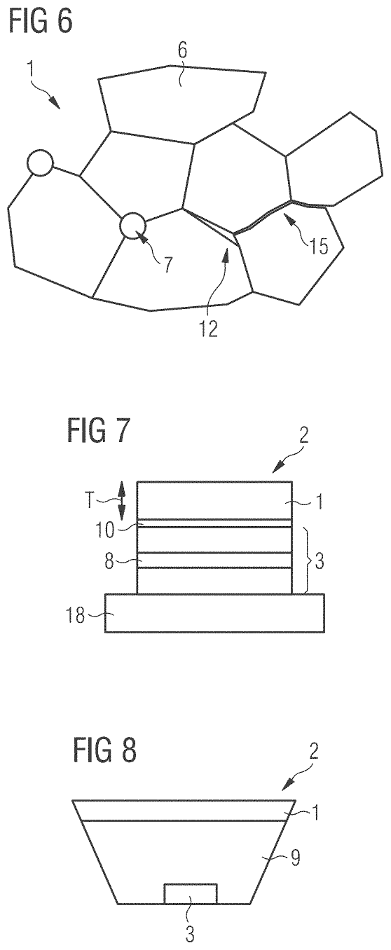

The comparative example illustrated in FIG. 6 shows a conversion element 1. The conversion element 1 comprises pores 7, grains 6, micro-cracks 15 and grain boundaries 12. The grains 6 show grain boundaries 12 between other adjacent grains 6 and adjacent pores 7. If there are fewer grain boundaries 12, then there is less grain boundary 12 scattering, which improves the efficiency.

FIG. 7 shows a radiation-emitting semiconductor device 2 according to an exemplary embodiment. The radiation-emitting semiconductor device 2 comprises a radiation-emitting semiconductor element 3 and a conversion element 1 as well as an adhesive 10. The radiation-emitting semiconductor element 3 is arranged on a leadframe 18. The radiation-emitting semiconductor element 3 can be a light-emitting diode chip or a laser diode chip having an epitaxially grown semiconductor layer sequence with an active region 8 which is suitable for generating electromagnetic primary radiation. The conversion element 1 is attached in the shape of a foil, a layer or a platelet downstream of the radiation-emitting semiconductor element 3.

By way of example, the conversion element 1 is arranged with an adhesive 10 in contact with the radiation-emitting semiconductor element 3. The thickness T of the conversion element 1 is dependent on the application of the device. The thickness T of the conversion element 1 is between at least 100 μm and at most 150 μm. The radiation-emitting semiconductor element 3 emits in operation electromagnetic primary radiation of the first wavelength range. The conversion element 1 converts electromagnetic primary radiation of the first wavelength range into electromagnetic secondary radiation of the second wavelength range. The conversion element 1 is adapted to partly or completely convert the electromagnetic primary radiation of the first wavelength range into electromagnetic secondary radiation of the second wavelength range. Alternatively, the conversion element 1 can be in direct contact with the radiation-emitting semiconductor element 3.

FIG. 8 differs from FIG. 7 in the arrangement of the conversion element 1 on the radiation-emitting semiconductor element 3. A potting material 9 surrounds in an exemplary embodiment the radiation-emitting semiconductor element 3. In this exemplary embodiment the radiation-emitting semiconductor element 3 is embedded into the potting material 9. In direct contact to the potting material 9 the conversion element 1 is arranged.

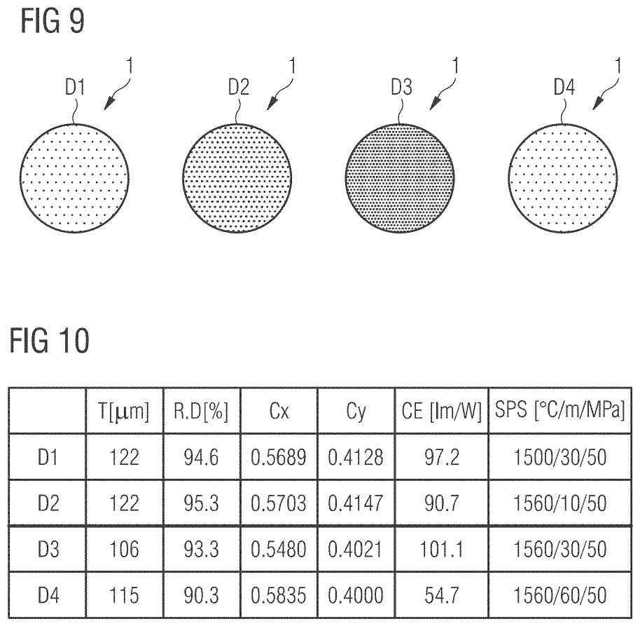

According to an exemplary embodiment, FIG. 9 shows four discs of a conversion element 1 obtained by adding 0.5 wt % barium fluoride as the flux material 5 to a powder of the starting material BaSrSiN:Eu.

The figures show the images of the conversion element 1 sintered under different sintering conditions from flux material 5 added powders of the starting material 13. The conversion element 1 in disc D1 is sintered at 1500° C. for 30 minutes under a pressure of 50 MPa. The conversion element 1 of disc D2 is sintered at 1560° C. for 10 minutes under a pressure of 50 MPa, whereas the conversion element 1 of disc D3 is sintered at 1560° C. for 30 minutes under a pressure of 50 MPa. The conversion element 1 of disc D4 is sintered at 1560° C. for 60 minutes under a pressure of 50 MPa (see FIG. 10).

After sintering, the discs are thinned down to a thickness of about 120 μm and measured with a tester for optical performance. Therefore, the discs are placed on a platform with a 0.6 millimeter diameter pinhole where electromagnetic primary radiation of a first wavelength range in the spectral region of blue light with a dominant spectral region of 400 nanometers to 480 nanometers shines through. The converted electromagnetic secondary radiation of a second wavelength range in the spectral region of amber light is measured by a sphere right above the sample disc. The measurement results are listed in FIG. 10. The discs D1 and D3 sintered for 30 minutes have a higher conversion efficiency CE value than comparable discs which are sintered for 10 minutes, for example, disc D2. If the temperature is 1560° C. and the sintering takes 60 minutes, the disc D4 shows darkening and decomposition of the conversion element 1 may occur. This results in a low conversion efficiency CE. T is the value for the thickness of the disc. R.D is the relative density. CX and CY are the color coordinates and SPS means the conditions of the sintering process. The thickness T of the disc is between 106 μm and 122 μm. A small thickness T of the conversion element 1 leads to a lower scattering of the electromagnetic radiation in comparison to thicker conversion elements 1.

The relative densities R.D of the conversion elements 1 shown in FIGS. 9 and 10 have a value between at least 90.3% and at most 95.3%. Here, the relative density R.D shows the ratio between the grains 6 and flux material 5 against the pores 7, wherein the grains 6 and flux material 5 have a percentage of between 90.3% and 95.3% of the conversion element 1 and the residual percentage are pores 7. This relative density R.D leads to an improved denser conversion element 1, which leads to an improved reduction of scattering of the electromagnetic radiation. Furthermore, there is preferably no proportional relation between the relative density R.D and the efficiency. The efficiency of an electromagnetic radiation depends also on the diameter of the grain 6. The color coordinate CX is in a range from 0.54 to 0.58 and the color coordinate CY is in a range from 0.50 to 0.51.

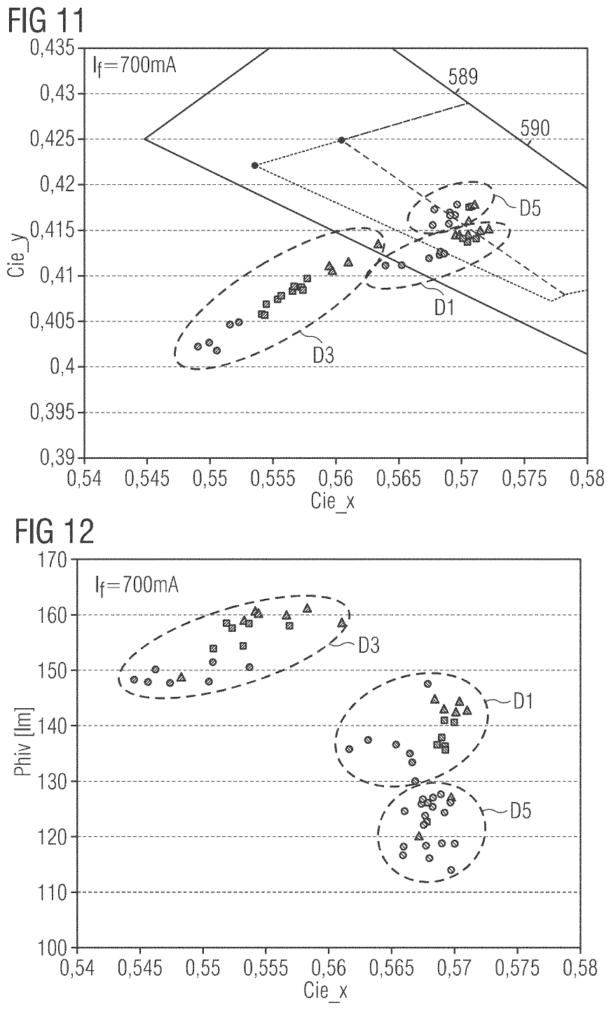

FIGS. 11 and 12 show a graphical view of color coordinates and luminous flux of a conversion element 1. Discs D1 and D3 are selected from FIGS. 9 and 10 and sintered from flux material 5 added powders of the starting material 13 and are diced into platelets and assembled into radiation-emitting semiconductor devices. Furthermore, one more conversion element 1 disc D5, which is sintered without flux material 5, is diced into platelets. The drive current I_{f} of the radiation-emitting semiconductor devices for the measurements is 700 mA.

In FIG. 11 the color coordinate CX is plotted against the color coordinate CY. Discs D1, D3 and D5 emit electromagnetic secondary radiation of a second wavelength range in the spectral region of amber light.

In FIG. 12 the color coordinate CX is plotted against the coordinate of luminous flux. Discs D1 and D3, using flux material 5 added conversion elements 1, have a higher luminous flux. From FIG. 12 it becomes clear that at similar color coordinates CX discs D1 and D3 have an about 13% higher luminous flux than reference disc D5 using conversion elements 1 without flux materials 5. The efficiency improvement is believed to stem from the significantly smaller degree of scattering of the electromagnetic radiation within the conversion element 1 due to larger grains 6 and fewer pores 7 in flux material 5 added conversion elements 1.

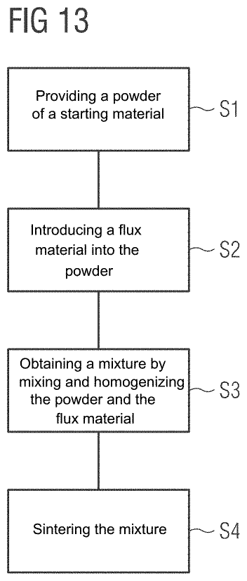

In FIG. 13 an exemplary embodiment of a method for producing a conversion element 1 with the method steps S1 to S4 is shown.

In the first method step S1 a powder of a starting material 13 is provided. The powder of the starting material 13 has a diameter of the particles 27 from between at least 0.1 micrometer and at most 1 micrometer.

In method step S2 a flux material 5 is introduced into the powder of the starting material 13. The flux material 5 can be added on the one hand as a starting raw material when making the powder of the starting material 13 or on the other hand it can be added into already made powders of the starting material 13. If the flux material 5 is added as a starting raw material when making the powder of the starting material 13, this advantageously leads to an improved homogenization, since the powder is coated with the flux material 5.

In method step S3 a mixture 21 comprising the flux material 5 and the powder of the starting material 13 is obtained by mixing and homogenization.

In the last method step S4 the mixture 21 is sintered at a temperature between at least 1500° C. and at most 1600° C. to obtain the conversion element 1.

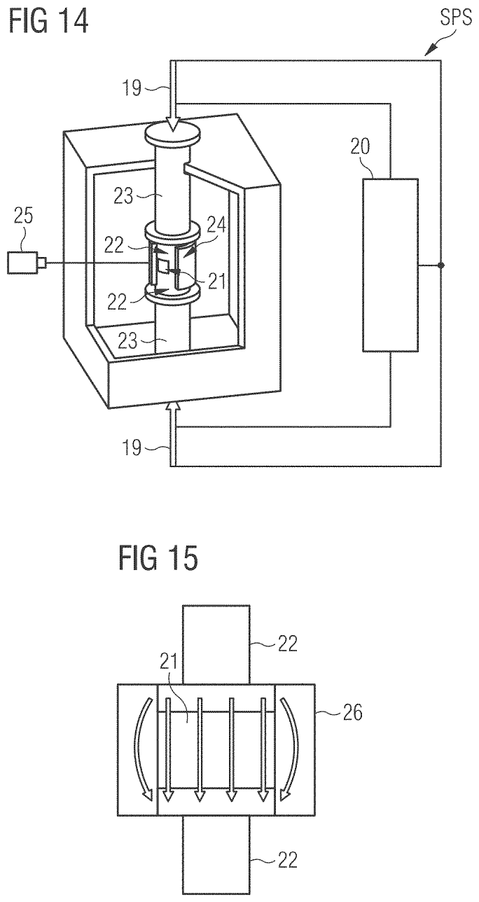

FIG. 14 shows a spark plasma sintering SPS machine comprising a mixture 21, a punch 22, electrodes 23, a graphite die 24, a pyrometer 25, a generator 20 and a hydraulic press 19. The mixture 21 is put into the graphite die 24 having a 20 millimeter inner diameter which is surrounded by a graphite cylinder 26. Afterwards the hydraulic press 19 exerts pressure on the mixture 21. Furthermore a current and a voltage are applied. The pyrometer 25 controls the temperature of the mixture 21. The mixture 21 is sintered under a nitrogen atmosphere at a peak temperature, between at least 20 minutes and at most 50 minutes with the maximum pressure of 50 MPa. The hydraulic press 19 exerts pressure on the punch 22, which leads to high pressure on the mixture 21 which is in a graphite cylinder 26 and leads to sintering of the conversion element (shown in FIG. 15).

The features and embodiments described in connection with the figures can be combined with each other according to further embodiments, even if not all combinations are explicitly described. Furthermore, the embodiments described in connection with the figures may alternatively or additionally comprise further features as described in the general part.

The invention is not limited by the description based on the embodiments of this, rather the invention encompasses any novel features as well as any combination of features, which includes in particular any combination of features in the patent claims, even if this feature or combination itself is not explicitly stated in the patent as an exemplary embodiment.

1. A conversion element comprising:
a ceramic luminescent material; and
a flux material,
wherein the flux material has a boiling temperature above 1500° C. and/or a melting temperature below 1500° C., and
wherein the flux material has a concentration in the conversion element smaller or equal to 0.5 wt %.

2. The conversion element according to claim 1, wherein the flux material is selected from the group consisting of metal halides and nitride compounds.

3. The conversion element according to claim 1, wherein the flux material is selected from the group consisting of LiF, NaF, KF, SrF₂, CaF₂ and BaF₂.

4. The conversion element according to claim 1, wherein the ceramic luminescent material comprises at least two of the following elements or materials: alkaline metals, alkaline earth metals, rare-earth metals, La, Y, Si, N, Al, or O.

5. The conversion element according to claim 1, wherein the conversion element comprises grains and pores, and wherein the grains are formed with the ceramic luminescent material and the pores are filled with a gas.

6. The conversion element according to claim 1, wherein a density of the conversion element is between 93.0% and 96.0%.

7. A radiation-emitting semiconductor device comprising:
a radiation-emitting semiconductor element, and
the conversion element according to claim 1.

8. The radiation-emitting semiconductor device according to claim 7,
wherein the radiation-emitting semiconductor element is configured to emit an electromagnetic primary radiation of a first wavelength range in a spectral region of blue light, and
wherein the conversion element is configured to convert the electromagnetic primary radiation of the first wavelength range into electromagnetic secondary radiation of a second wavelength range in a spectral region of amber light.

9-15. (canceled)

16. A conversion element comprising:
a ceramic luminescent material; and
a flux material,
wherein the flux material has a boiling temperature above 1500° C. and/or a melting temperature below 1500° C.,
wherein the flux material has a concentration in the conversion element smaller or equal to 0.5 wt %,
wherein the flux material is comprises LiF, NaF or KF, and
wherein the ceramic luminescent material comprises at least two of the following elements or materials: alkaline metals, alkaline earth metals, rare-earth metals, La, Y, Si, N, Al, or O.

17. The conversion element according to claim 16, wherein the conversion element comprises grains and pores.

18. The conversion element according to claim 17, wherein the grains are formed with the ceramic luminescent material and the pores are filled with a gas.

19. The conversion element according to claim 16, wherein a density of the conversion element is between 93.0% and 96.0%.

20. A radiation-emitting semiconductor device comprising:
a radiation-emitting semiconductor element, and
the conversion element according to claim 16.

21. The radiation-emitting semiconductor device according to claim 20,
wherein the radiation-emitting semiconductor element is configured to emit an electromagnetic primary radiation of a first wavelength range in a spectral region of blue light, and
wherein the conversion element is configured to convert the electromagnetic primary radiation of the first wavelength range into electromagnetic secondary radiation of a second wavelength range in a spectral region of amber light.

22. A conversion element comprising:
a ceramic luminescent material; and
a flux material,
wherein the flux material has a boiling temperature above 1500° C. and/or a melting temperature below 1500° C.,
wherein the flux material has a concentration in the conversion element smaller or equal to 0.5 wt %,
wherein the flux material is comprises SrF₂, CaF₂ or BaF₂, and
wherein the ceramic luminescent material comprises at least two of the following elements or materials: alkaline metals, alkaline earth metals, rare-earth metals, La, Y, Si, N, Al, or O.

23. The conversion element according to claim 22, wherein the conversion element comprises grains and pores.

24. The conversion element according to claim 23, wherein the grains are formed with the ceramic luminescent material and the pores are filled with a gas.

25. The conversion element according to claim 22, wherein a density of the conversion element is between 93.0% and 96.0%.

26. A radiation-emitting semiconductor device comprising:
a radiation-emitting semiconductor element, and
the conversion element according to claim 22.

27. The radiation-emitting semiconductor device according to claim 26,
wherein the radiation-emitting semiconductor element is configured to emit an electromagnetic primary radiation of a first wavelength range in a spectral region of blue light, and
wherein the conversion element is configured to convert the electromagnetic primary radiation of the first wavelength range into electromagnetic secondary radiation of a second wavelength range in a spectral region of amber light.
